(19) United States
(12) Patent Application Publication
(10) Pub. No.: US 2006/0076574 A1
(43) Pub. Date: Apr. 13, 2006

(54) Gallium-nitride based light-emitting diodes structure with high reverse withstanding voltage and anti-ESD capability

(76) Inventors: Liang-Wen Wu, Banciao City (TW); Fen-Ren Chien, Yonghe City (TW)

Correspondence Address: SUPREME PATENT SERVICES, P.O. BOX 2339, SARATOGA, CA, 95070-0339, US

(21) Appl. No.: 11/266,415

(22) Filed: Nov. 3, 2005

Related U.S. Application Data
(63) Continuation-in-part of application No. 10/964,350, filed on Oct. 12, 2004.

(51) Int. Cl. H01L 33/00

(52) U.S. Cl. 257/103

(57) ABSTRACT

An epitaxial structure for GaN-based LEDs to achieve better reverse withstanding voltage and anti-ESD capability is provided herein. The epitaxial structure has an additional anti-ESD thin layer as the topmost layer, which is made of undoped indium-gallium-nitrides (InGaN) or low-band-gap (Eg<3.4 eV), undoped aluminum-indium-gallium-nitrides (AlInGaN). The anti-ESD thin layer could also have a superlattice structure formed by interleaving at least an undoped InGaN thin layer and at least a low-band-gap, undoped AlInGaN thin layer. This anti-ESD thin layer greatly improves the GaN-based LEDs' reverse withstanding voltage and resistivity to ESD, which in turn extends the GaN-based LEDs' operation life significantly.

### CROSS-REFERENCE TO RELATED APPLICATIONS

This is a continuation-in-part of U.S. application Ser. No. 10/964,350, filed on Oct. 12, 2004.

### BACKGROUND OF THE INVENTION

1. Field of the Invention

The present invention generally relates to the gallium-nitride based light-emitting diodes and, more particularly, to an epitaxial structure of the gallium-nitride based light-emitting diodes having a high reverse withstanding voltage and a high resistivity to electrostatic discharge.

2. The Prior Arts

Gallium-nitride (GaN) based light-emitting diodes (LEDs), as various color LEDs can be developed by controlling the GaN-based material's composition, has been the research and development focus in the academic arena and in the industries as well in recent years. Besides being applied in the display of consumer electronic appliances such as digital clocks and cellular handsets, technology breakthroughs in terms of luminance and lighting efficiency has led GaN-based LEDs into applications such as outdoor display panels and automobile lamps.

To have practical applicability in these outdoor display devices, besides having high luminance and lighting efficiency, GaN-based LEDs must have a rather high reverse withstanding voltage and high resistivity to electrostatic discharge (ESD), so that they can continue to operate for an extended period of time under the harsh, outdoor environment.

However, for conventional GaN-based LEDs, they have a traditional epitaxial structure by growing GaN-based nitrides on a sapphire substrate. GaN-based nitrides and the sapphire substrate usually have mismatched lattice constants, causing an excessive accumulation of stresses and, thereby, causing the GaN-based LEDs to have an inferior epitaxial quality. The GaN-based LEDs' anti-ESD capability and reverse withstanding voltage are therefore degraded.

The most widely adopted solution in recent years is to use a flip-chip process to combine a GaN-based LED with a Zener diode made of silicon. Although this solution indeed effectively improves the GaN-based LED's anti-ESD capability, the flip-chip process is much more complicated than the traditional manufacturing process for general GaN-based LEDs.

Accordingly, the present invention is directed to overcome the foregoing disadvantages of conventional GaN-based LEDs of the prior arts.

### SUMMARY OF THE INVENTION

The present invention provides an epitaxial structure for the GaN-based LEDs so that the limitations and disadvantages in terms of their anti-ESD capability from the prior arts can be obviated practically.

The most significant difference between the GaN-based LEDs according to the present invention and those of the prior arts lies in the formation of an anti-ESD thin layer made of undoped indium-gallium-nitrides (InGaN) or low-band-gap (Eg<3.4 eV), undoped aluminum-indium-gallium-nitrides (AlInGaN) beneath the transparent conductive layer of traditional GaN-based LEDs. The anti-ESD thin layer could also have a superlattice structure formed by interleaving a plurality of InGaN thin layers and a plurality of low-band-gap, undoped AlInGaN thin layers. This anti-ESD thin layer greatly improves the GaN-based LEDs' reverse withstanding voltage and resistivity to ESD, which in turn extends the GaN-based LEDs' operation life significantly.

FIGS. 1(a) and 1(b) of the attached drawings illustrate the maximum ESD voltage and the reverse withstanding voltage of a GaN-based LED according the present invention versus the thickness of the GaN-based LED's anti-ESD thin layer. As shown in FIGS. 1(a) and 1(b), an anti-ESD thin layer made of undoped In_{0.2}Ga_{0.8}N obviously provides much higher reverse withstanding voltage and maximum ESD voltage than anti-ESD thin layers made of Si-doped and Mg-doped In_{0.2}Ga_{0.8}N, when all three anti-ESD layers are of a same thickness between 5 Å and 100 Å.

Besides the foregoing advantages, due to the low band gap characteristics of undoped InGaN and undoped AlInGaN, an anti-ESD thin layer made of such material, in comparison to the traditional n-type or p-type contact layer in a GaN-based LED of the prior art, has a lower resistivity (and, thereby, is easier to form ohmic contact) between the anti-ESD thin layer and the metallic electrode or transparent conductive layer above.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIGS. 1(a) and 1(b) illustrate the maximum ESD voltage and the reverse withstanding voltage of a GaN-based LED according to the present invention versus the thickness of the GaN-based LED's anti-ESD thin layer.

FIG. 2 is a schematic diagram showing a GaN-based LED device according to a first embodiment of the present invention.

FIG. 3 is a schematic diagram showing a GaN-based LED device according to a second embodiment of the present invention.

FIG. 4 is a schematic diagram showing a GaN-based LED device according to a third embodiment of the present invention.

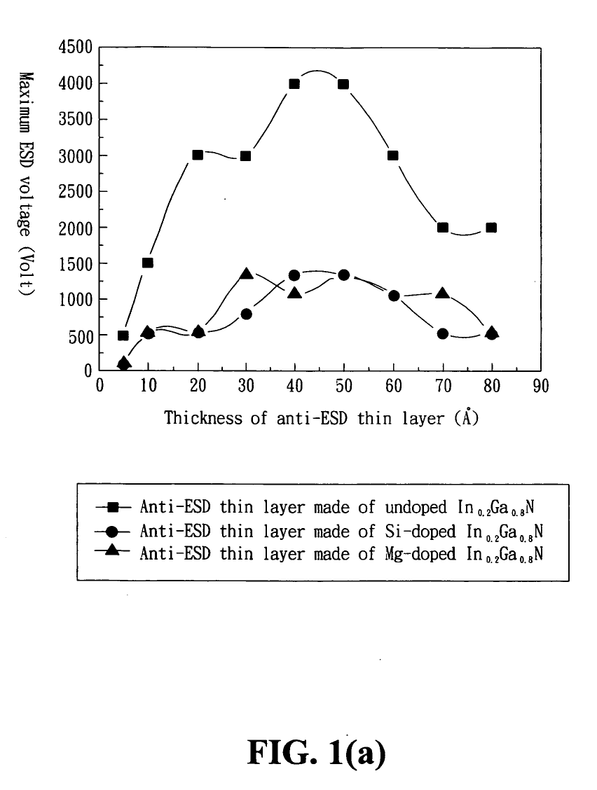

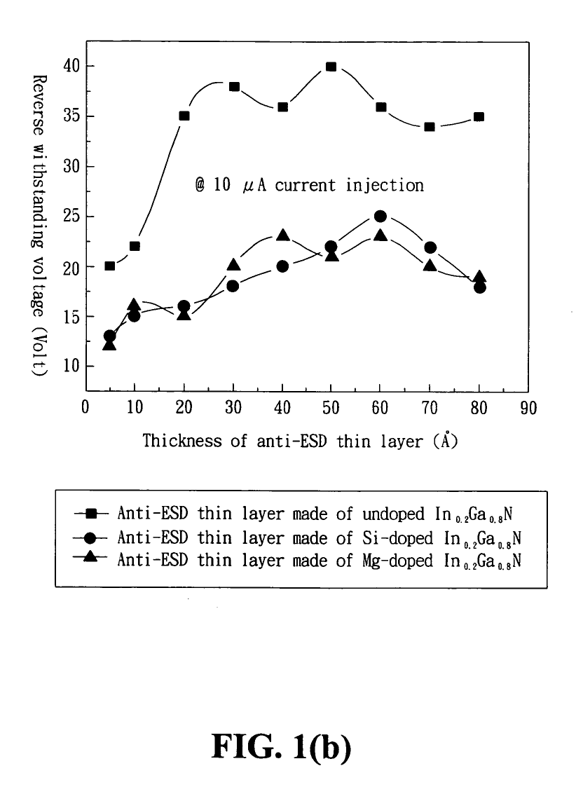

### DETAILED DESCRIPTION OF THE PREFERRED EMBODIMENTS

In the following, detailed description along with the accompanied drawings is given to better explain preferred embodiments of the present invention. Please be noted that, in the accompanied drawings, some parts are not drawn to scale or are somewhat exaggerated, so that people skilled in the art can better understand the principles of the present invention.

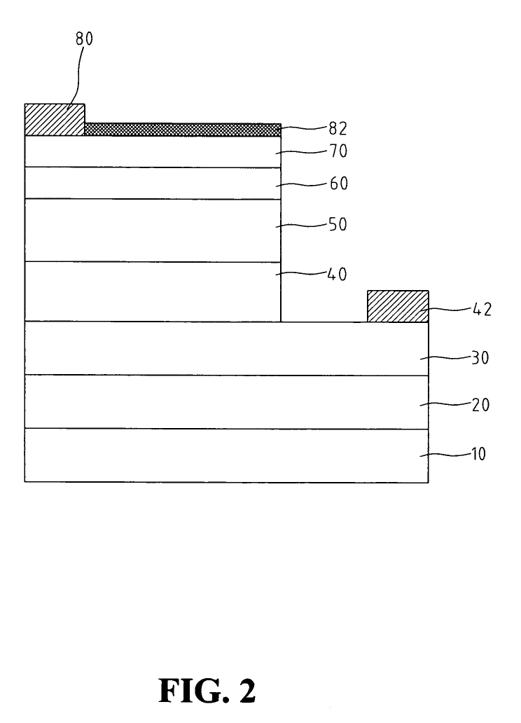

FIG. 2 is a schematic diagram showing a GaN-based LED device according to a first embodiment of the present invention. As shown in FIG. 2, the GaN-based LED device has a substrate 10 made of C-plane, R-plane, or A-plane aluminum-oxide monocrystalline (sapphire), or an oxide monocrystalline having a lattice constant compatible with that of nitride semiconductors. The substrate 10 can also be made of SiC (6H-SiC or 4H-SiC), Si, ZnO, GaAs, or MgAl₂O₄. Generally, the most common material used for the substrate 10 is sapphire or SiC. An optional buffer layer 20 made of a GaN-based material whose molecular formula could be expressed as AlaGa_{b}In_{1-a-b}N (0≦a,b<1, a+b≦1) having a specific composition is then formed on an upper side of the substrate 10. On top of the buffer layer 20, a first contact layer 30 is formed and made of a GaN-based material having a first conduction type (e.g., it could a p-typed GaN or n-typed GaN). Then, on top of the first contact layer 30, an active layer 40 made of a GaN-based material such as InGaN is formed on top of the first contact layer 30.

On top of the active layer 40, an optional cladding layer 50 made of a GaN-based material having a second conduction type opposite to that of the first contact layer 30. In other words, for example, if the first contact layer 30 is made of an n-typed GaN-based material, then the cladding layer 50 is made of a p-typed GaN-based material. Then, on top of the active layer 40 (if there is no cladding layer 50) or the cladding layer 50, a second contact layer 60 made of a GaN-based material having the second conduction type opposite to that of the first contact layer, and an anti-ESD thin layer 70 are sequentially stacked in this order from bottom to top. The anti-ESD thin layer 70 is the major characteristic of the present invention. In this first embodiment of the present invention, the anti-ESD thin layer 70 is made of undoped (i.e., without having any n-typed or p-typed impurities) In_{d}Ga_{1-d}N (0<d≦1) having a specific composition. The anti-ESD thin layer 70 has a thickness between 5 Å and 100 Å and is formed at a growing temperature between 600° C. and 1100° C.

Up to this point, the epitaxial structure of the present invention has been completed. To package the epitaxial structure into a LED device, the electrodes for the LED device have to be formed. Conventionally, the epitaxial structure is appropriately etched to expose a portion of the first contact layer 30 and, then, a first electrode 42 made of an appropriate metallic material is formed on top of the exposed first contact layer 30.

On the other hand, on top of the anti-ESD thin layer 70, an optional transparent conductive layer 82 could be formed. The transparent conductive layer 82 can be a metallic conductive layer or a transparent oxide layer. The metallic conductive layer is made of one of the materials including, but not limited to, Ni/Au alloy, Ni/Pt alloy, Ni/Pd alloy, Pd/Au alloy, Pt/Au alloy, Cr/Au alloy, Ni/Au/Be alloy, Ni/Cr/Au alloy, Ni/Pt/Au alloy, Ni/Pd/Au alloy, and other similar materials. The transparent oxide layer, on the other hand, is made of one of the materials including, but not limited to, ITO, CTO, ZnO:Al, ZnGa₂O₄, SnO₂:Sb, Ga₂O₃:Sn, AgInO₂:Sn, In₂O₃:Zn, CuAlO₂, LaCuOS, NiO, CuGaO₂, and SrCu₂O₂. A second electrode 80 is formed on top of the transparent conductive layer 82 or besides the transparent conductive layer 82 as shown in the accompanied drawings. The second electrode 80 is made of one of the materials including, but not limited to, Ni/Au alloy, Ni/Pt alloy, Ni/Pd alloy, Ni/Co alloy, Pd/Au alloy, Pt/Au alloy, Ti/Au alloy, Cr/Au alloy, Sn/Au alloy, Ta/Au alloy, TiN, TiWNₓ (x≧0), WSi_{y} (y≧0), and other similar metallic materials.

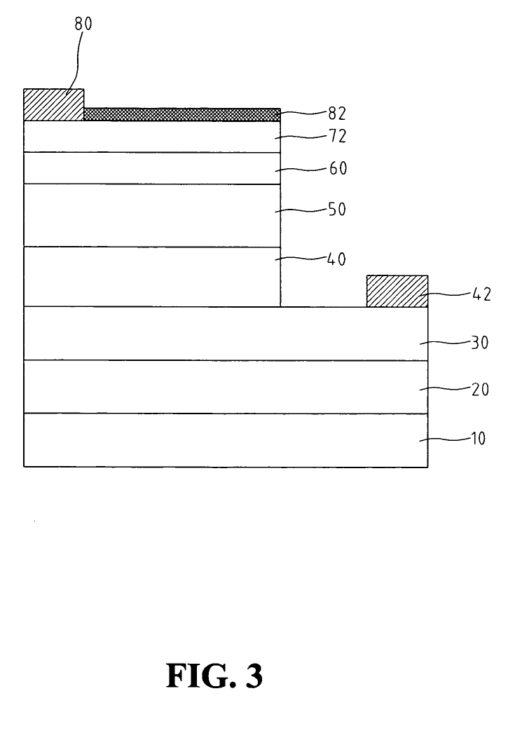

FIG. 3 is a schematic diagram showing a GaN-based LED device according to a second embodiment of the present invention. As shown in FIG. 3, this embodiment of the present invention has an identical structure as in the previous embodiment. The only difference lies in the material used for the anti-ESD thin layer. In this embodiment, the anti-ESD thin layer 72 is made of undoped, low-band-gap (Eg<3.4 eV) AlₑIn_{f}Ga_{1-e-f}N (0<e,f<1, e+f<1) having a specific composition. The anti-ESD thin layer 72 has a thickness between 5 Å and 100 Å and a growing temperature between 600° C. and 1100° C.

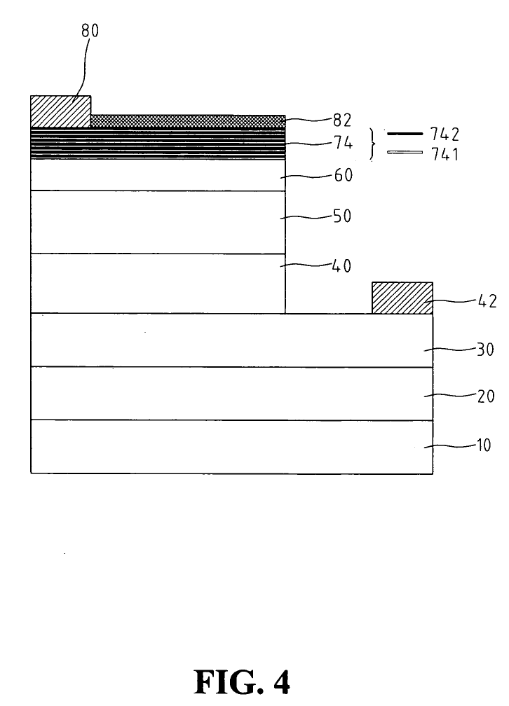

FIG. 4 is a schematic diagram showing a GaN-based LED according to a third embodiment of the present invention. As shown in FIG. 4, this embodiment of the present invention has an identical structure as in the previous embodiments. The only difference lies in the material used and the structure of the anti-ESD thin layer. In this embodiment, the anti-ESD thin layer 74 has a superlattice structure formed by interleaving one or more InGaN thin layers 741 with one or more AlInGaN thin layers 742. Each of the InGaN thin layers 741 is made of undoped In_{g}Ga_{1-g}N (0<g≦1) having a specific composition, and has a thickness between 5 Å and 20 Å, and is formed at a growing temperature between 600° C. and 1100° C. In addition, the In_{g}Ga_{1-g}N composition (i.e. the parameter g of the foregoing molecular formula) of each InGaN thin layer 741 is not required to be identical. On the other hand, each of the AlInGaN thin layers 742 is made of undoped, low-band-gap (Eg<3.4 eV) AlₕInᵢGa₁₋ₕ₋ᵢN (0<h,i<1, h+i<1) having a specific composition, and has a thickness between 5 Å and 20 Å, and is formed at a growing temperature between 600° C. and 1100° C. Similarly, the AlₕInᵢGa₁₋ₕ₋ᵢN composition (i.e. the parameters h and i of the foregoing molecular formula) of each AlInGaN thin layer 742 is not required to be identical.

Within the anti-ESD thin layer 74's superlattice structure, a InGaN thin layer 741 is at the bottom and, on top of the bottommost InGaN thin layer 741, a AlInGaN thin layer 742, another InGaN thin layer 741, etc., are alternately stacked upon each other in this repetitive fashion. In another variation of this embodiment, it is an AlInGaN thin layer 742 that is at the bottom. Then, on top of the bottommost AlInGaN thin layer 742, an InGaN thin layer 741, another AlInGaN thin layer 742, etc., are alternately stacked upon each other in this repetitive fashion. In other words, the InGaN thin layer 741 and the AlInGaN thin layer 742 are repetitively and alternately stacked. The repetition count is at least one (i.e. there are at least one layer of the InGaN thin layer 741 and at least one layer of the AlInGaN thin layer). The total thickness of the anti-ESD thin layer 74 is at most 200 Å.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A GaN-based LED structure, comprising:
a substrate;
a first contact layer made of a GaN-based material having a first conduction type located on top of said substrate;
an active layer made of a GaN-based material located on top of said first contact layer;
a second contact layer made of a GaN-based material having a second conduction type opposite to said first conduction type located on top of said active layer; and
an anti-ESD thin layer made of at least an undoped GaN-based material located on top of said second contact layer.

2. The GaN-based LED structure as claimed in claim 1, wherein said active layer is made of InGaN.

3. The GaN-based LED structure as claimed in claim 1, wherein said anti-ESD thin layer is made of undoped In_{d}Ga_{1-d}N (0<d≦1 ) having a specific composition.

4. The GaN-based LED structure as claimed in claim 3, wherein said anti-ESD thin layer has a thickness between 5 Å and 100 Å.

5. The GaN-based LED structure as claimed in claim 1, wherein said anti-ESD thin layer is made of undoped AlₑIn_{f}Ga_{1-e-f}N (0<e,f<1, e+f<1) having a specific composition.

6. The GaN-based LED structure as claimed in claim 5, wherein said anti-ESD thin layer has a thickness between 5 Å and 100 Å.

7. The GaN-based LED structure as claimed in claim 5, wherein said anti-ESD thin layer has a band gap less than 3.4 eV.

8. The GaN-based LED structure as claimed in claim 1, wherein said anti-ESD thin layer has a superlattice structure having at least an undoped InₖGa₁₋ₖN (0<k≦1) thin layer and at least an undoped AlₚIn_{q}Ga_{1-p-q}N (0<p,q<1, p+q<1) thin layer alternately stacked upon each other.

9. The GaN-based LED structure as claimed in claim 8, wherein said anti-ESD thin layer has a thickness no more than 200 Å, and each of said InₖGa₁₋ₖN thin layers and AlₚIn_{q}Ga_{1-p-q}N thin layers has a thickness between 5 Å and 20 Å.

10. The GaN-based LED structure as claimed in claim 8, wherein each of said AlₚIn_{q}Ga_{1-p-q}N thin layers has a band gap less than 3.4 eV.

11. The GaN-based LED structure as claimed in claim 1, further comprising a buffer layer made of a GaN-based material interposed between said substrate and said first contact layer.

12. The GaN-based LED structure as claimed in claim 11, wherein said buffer layer is made of AlₐGa_{b}In_{1-a-b}N (0≦a,b<1, a+b≦1) having a specific composition.

13. The GaN-based LED structure as claimed in claim 1, further comprising a cladding layer made of a GaN-based material having said second conduction type interposed between said active layer and said second contact layer.

14. A GaN-based LED device, comprising:
a substrate;
a buffer layer made of AlₐGa_{b}In_{1-a-b}N (0≦a,b<1, a+b≦1) having a specific composition located on top of an upper side of said substrate;
a first contact layer made of a GaN-based material having a first conduction type located on top of said buffer layer;
an active layer made of InGaN located on top of a part of said first contact layer's upper surface;
a first electrode located on top of another part of said first contact layer's upper surface not covered by said active layer;
a second contact layer made of a GaN-based material having a second conduction type opposite to said first conduction type located on top of said active layer;
an anti-ESD thin layer made of at least an undoped GaN-based material;
a transparent conductive layer that is one of a metallic conductive layer and a transparent oxide layer located on top of said anti-ESD thin layer's upper surface; and
a second electrode located on top of said transparent conductive layer or on top of another part of said anti-ESD thin layer's upper surface not covered by said transparent conductive layer.

15. The GaN-based LED device as claimed in claim 14, wherein said anti-ESD thin layer has a thickness between 5 Å and 100 Å, and is made of undoped In_{d}Ga_{1-d}N (0<d≦1) having a specific composition.

16. The GaN-based LED device as claimed in claim 14, wherein said anti-ESD thin layer has a thickness between 5 Å and 100 Å, and is made of undoped AlₑIn_{f}Ga_{1-e-f}N (0<e,f<1, e+f<1) having a specific composition and a band gap less than 3.4 eV.

17. The GaN-based LED device as claimed in claim 14, wherein said anti-ESD layer has a thickness no more than 200 Å and has a superlattice structure having at least an undoped InₖGa₁₋ₖN (0<k≦1) thin layer and at least an undoped AlₚIn_{q}Ga_{1-p-q}N (0<p,q<1, p+q<1) thin layer alternately stacked upon each other; each of said InₖGa₁₋ₖN thin layers and AlₚIn_{q}Ga_{1-p-q}N thin layers has a thickness between 5 Å and 20 Å; and each of said AlₚIn_{q}Ga_{1-p-q}N thin layers has a band gap less than 3.4 eV.

18. The GaN-based LED device as claimed in claim 14, wherein said metallic conductive layer is made of a material selected from the group consisting of Ni/Au alloy, Ni/Pt alloy, Ni/Pd alloy, Pd/Au alloy, Pt/Au alloy, Cr/Au alloy, Ni/Au/Be alloy, Ni/Cr/Au alloy, Ni/Pt/Au alloy, and Ni/Pd/Au alloy

19. The GaN-based LED device as claimed in claim 14, wherein said transparent oxide layer is made of a material selected from the group consisting of ITO, CTO, ZnO:Al, ZnGa₂O₄, SnO₂:Sb, Ga₂O₃:Sn, AgInO₂:Sn, In₂O₃:Zn, CuAlO₂, LaCuOS, NiO, CuGaO₂, and SrCu₂O₂.

20. The GaN-based LED device as claimed in claim 14, wherein said second electrode is made of a material selected from the group consisting of Ni/Au alloy, Ni/Pt alloy, Ni/Pd alloy, Ni/Co alloy, Pd/Au alloy, Pt/Au alloy, Ti/Au alloy, Cr/Au alloy, Sn/Au alloy, Ta/Au alloy, TiN, TiWNₓ (x≧0), and WSi_{y} (y≧0).

21. The GaN-based LED device as claimed in claim 14, further comprising a cladding layer made of a GaN-based material having said second conduction type interposed between said active layer and said second contact layer.
